(19) United States
(12) Patent Application Publication
(10) Pub. No.: US 2019/0272489 A1
(43) Pub. Date: Sep. 5, 2019

(54) VISUAL COST ESTIMATING FOR EARLY PHASE PROJECT PLANNING

(71) Applicant: NLW Consulting LLC, Spring, TX (US)

(72) Inventor: Nelson L. Ward, Spring, TX (US)

(21) Appl. No.: 15/911,031

(22) Filed: Mar. 2, 2018

(51) Int. Cl. G06Q 10/06; G06Q 30/02; G06F 3/0484; G06F 3/0481

(52) U.S. Cl. CPC G06Q 10/06313; G06F 3/04815; G06F 3/04845; G06Q 30/0283

(57) ABSTRACT

A method of visual cost estimating includes providing a graphical user interface having a scaled workspace corresponding to a project space, placing a graphical representation of one or more project items on or within the scaled workspace, adjusting a layout of one or more project items on or within the scaled workspace according to a user's preference, one or more predetermined rules relating to one or more project items, or a relationship between two or more project items, adjusting a quantity of one or more project items previously placed based on the layout of one or more project items on or within the scaled workspace or adding one or more project items based on the layout of one or more project items previously placed or a relationship between two or more project items previously placed, and generating a visual cost estimate corresponding to the layout of project items.

### BACKGROUND OF THE INVENTION

Organizations contemplating future capital projects rely on early phase cost estimates to make initial budgetary as well as feasibility determinations. Historically, early phase cost estimates are poor predictors of actual costs and oftentimes are merely on the order-of-magnitude of actual costs incurred. These early phase cost estimates are revised as a project progresses from initial proposal through planning, layout, design, and construction. Frequently, actual project costs incurred in later phases of the project are multiples of the early phase cost estimates and may render the project economically impracticable. As such, a longstanding goal of early phase cost estimating has been to provide a more accurate cost estimate as early in the project cycle as is possible. However, early phase cost estimating is more art than science and accurate cost estimating has proven difficult for complex capital projects in the oil and gas industry.

### BRIEF SUMMARY OF THE INVENTION

According to one aspect of one or more embodiments of the present invention, a method of visual cost estimating includes providing a graphical user interface having a scaled workspace corresponding to a project space, placing a graphical representation of one or more project items on or within the scaled workspace, adjusting a layout of one or more project items on or within the scaled workspace according to a user's preference, one or more predetermined rules relating to one or more project items, or a relationship between two or more project items, adjusting a quantity of one or more project items previously placed based on the layout of one or more project items on or within the scaled workspace or adding one or more project items based on the layout of one or more project items previously placed or a relationship between two or more project items previously placed, and generating a visual cost estimate corresponding to the layout of project items on or within the scaled workspace.

According to one aspect of one or more embodiments of the present invention, a non-transitory computer readable medium comprising software instructions that, when executed by a processor, performs a method of visual cost estimating includes providing a graphical user interface having a scaled workspace corresponding to a project space, placing a graphical representation of one or more project items on or within the scaled workspace, adjusting a layout of one or more project items on or within the scaled workspace according to a user's preference, one or more predetermined rules relating to one or more project items, or a relationship between two or more project items, adjusting a quantity of one or more project items previously placed based on the layout of one or more project items on or within the scaled workspace or adding one or more project items based on the layout of one or more project items previously placed or a relationship between two or more project items previously placed, and generating a visual cost estimate corresponding to the layout of project items on or within the scaled workspace.

Other aspects of the present invention will be apparent from the following description and claims.

### BRIEF DESCRIPTION OF THE DRAWINGS

FIG. 1A shows an exemplary conventional early phase cost estimate for a complex capital project.

FIG. 1B shows an exemplary itemized list of equipment and bulk material for the complex capital project.

FIG. 2 shows a computing system for visual cost estimating in accordance with one or more embodiments of the present invention.

FIG. 3 shows a block diagram of a visual cost estimating software application in accordance with one or more embodiments of the present invention.

FIG. 4A shows a scaled workspace corresponding to a project space in accordance with one or more embodiments of the present invention.

FIG. 4B shows a graphical representation of one or more project items placed on the scaled workspace in accordance with one or more embodiments of the present invention.

FIG. 4C shows an adjusted layout of one or more project items on the scaled workspace according to a user's preference, one or more predetermined rules relating to one or more project items, or a relationship between two or more project items in accordance with one or more embodiments of the present invention.

FIG. 4D shows a final layout of one or more project items on the scaled workspace according to one or more embodiments of the present invention.

FIG. 4E shows a visual depiction of a distribution of cost for material costs corresponding to the layout of one or more project items on the scaled workspace in accordance with one or more embodiments of the present invention.

FIG. 4F shows a visual depiction of a distribution of cost for labor costs corresponding to the layout of one or more project items on the scaled workspace in accordance with one or more embodiments of the present invention.

FIG. 5A shows a visual cost estimate for a complex capital project in accordance with one or more embodiments of the present invention.

FIG. 5B shows an exemplary itemized list of equipment and bulk material for the complex capital project in accordance with one or more embodiments of the present invention.

FIG. 6 shows a method of visual cost estimating in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

Complex capital projects in the oil and gas industry are somewhat unique in that they require a substantial amount of complex and interrelated equipment, material, and labor. The layout of midstream and downstream process plants is complicated by constraints on the project space and the interrelated nature of the equipment that must work together to perform various processes. In addition, maintenance, safety, and constructability issues must be taken into consideration and further complicate the layout of such facilities. However, conventional early phase cost estimating in complex capital projects is disconnected from, and bears no relation to, the actual project space and substantially underestimates project costs.

This is not entirely surprising given that conventional early phase cost estimating in the oil and gas industry is performed by estimators, of various experience levels, that merely generate itemized lists of equipment, supporting structures, connectivity, and labor costs. This conventional method of early phase cost estimating is highly dependent on the experience of the estimator and is completely disconnected from, and typically has no relation to, the actual project space or its layout. This is problematic because the spatial relationships and the special requirements of the equipment, supporting structures, and connectivity that drive the layout of the facility are inextricably intertwined with the actual project space and, consequently, the actual project costs. As a consequence, conventional cost estimates tend to substantially underestimate required material and labor, resulting in project creep and cost overruns that are typically not identified until later detailed design phases of the project or during actual construction. These cost overruns tend to be multiples of the conventional early phase cost estimate, and, in some instances, render the project economically impracticable. As such, integrating early phase cost estimating and project planning provides the greatest opportunity to positively impact layout, design, and control capital costs.

Accordingly, in one or more embodiments of the present invention, a method of visual cost estimating provides an early phase cost estimate based on an interactive visual layout of project items on or within a scaled workspace corresponding to a project space that is substantially more accurate than conventional cost estimates. The visual cost estimate is more closely aligned to the actual project space where the facility is to be constructed. A visual depiction of a distribution of material and labor costs corresponding to the layout of project items on or within the scaled workspace provides visual focus on the actual cost drivers of the project. Advantageously, the visual cost estimate allows interested parties to visualize the layout of the facility and the associated cost drivers, facilitates communication of project scope and cost, and simplifies project review and management. In addition, alternate layout scenarios, and their cost impact, may be visually evaluated for budgetary and feasibility determinations.

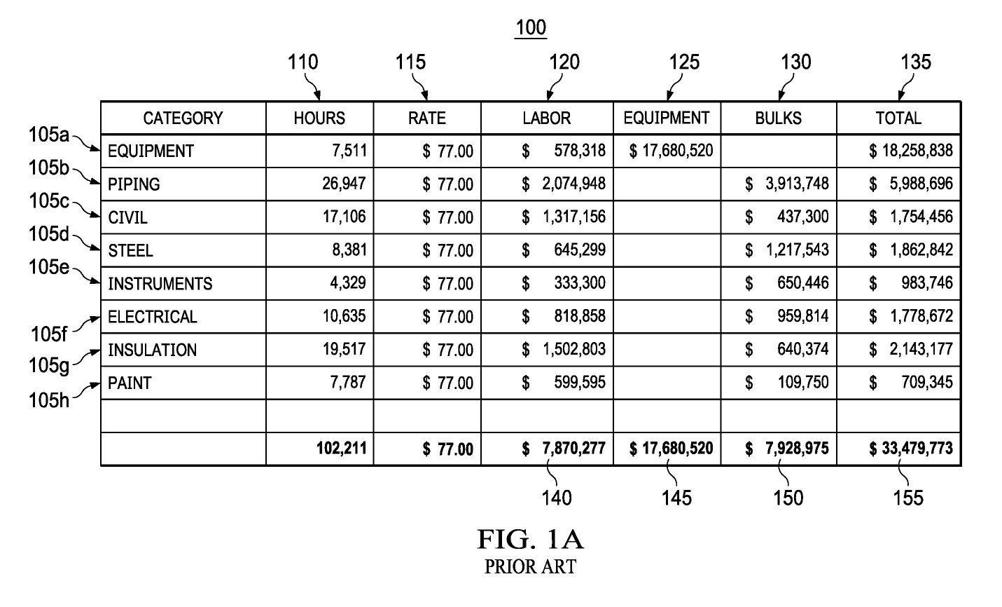

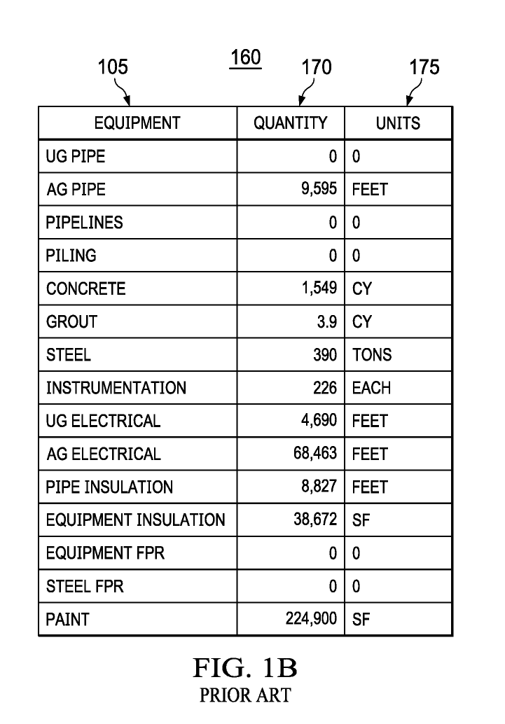

FIG. 1A shows an exemplary conventional early phase cost estimate 100 for a complex capital project. As previously discussed, conventional early phase cost estimates are typically itemized lists of costs, typically prepared in a spreadsheet software application. The conventional early phase cost estimate 100 depicted in FIG. 1A is an exemplary spreadsheet that includes, from top to bottom, a plurality of categorical line items 105a through 105h, where each line item extends across the page horizontally and corresponds to estimated costs associated with that category. Within each categorical line item 105, the hours 110 represents an estimate of the number of hours of labor required for that category, the hourly rate 115 represents the hourly rate for labor, and the labor cost 120 is calculated by multiplying the number of hours 110 by the hourly rate 115 and represents the estimated labor cost for the respective category. The equipment cost 125 represents an estimate of equipment cost for the respective category and the bulk cost 130 represents the cost of all other supporting structure and material required for that category. Early phase cost estimate 100 includes a categorical line item sub-total 135, a sub-total of labor cost 140, a sub-total of equipment cost 145, a sub-total of bulk cost 150, and a total early phase cost estimate 155.

While the early phase cost estimate 100 depicted in FIG. 1 is a summary, each categorical line item 105 corresponds to an itemized list within that category (not independently illustrated) that is summarized within its respective categorical line item 105. For example, the categorical line item entry for equipment 105a as depicted in FIG. 1A may correspond to an itemized list of various equipment (not independently illustrated) that is summarized within the categorical line item 105a. In many instances, each categorical line item 105 may be expanded to show the itemized list (not shown), if any, within that category. For complex capital projects in the oil and gas industry, the expanded early phase cost estimate (not shown) may be many thousands of lines long (not shown) and consolidated and summarized as presented in FIG. 1A.

Continuing, FIG. 1B shows an exemplary itemized list 160 of equipment 105a and bulk material for the complex capital project. As discussed above, the categorical line item 105a for equipment shown in FIG. 1A represents a summary of an itemized list of equipment, the components of which are not shown in the summary view of FIG. 1A. In FIG. 1B, the itemized list 160 includes a column showing a type of equipment 165, a column showing its respective quantity 170, and a column showing units 175. The itemized list 160 may include other information not shown such as, for example, cost and a sub-total for each respective type of equipment 165. The exemplary conventional early phase cost estimate of FIG. 1A and itemized list of equipment of FIG. 1B may be used for purposes of illustration when discussing one or more embodiments of the method of visual costing estimating discussed herein.

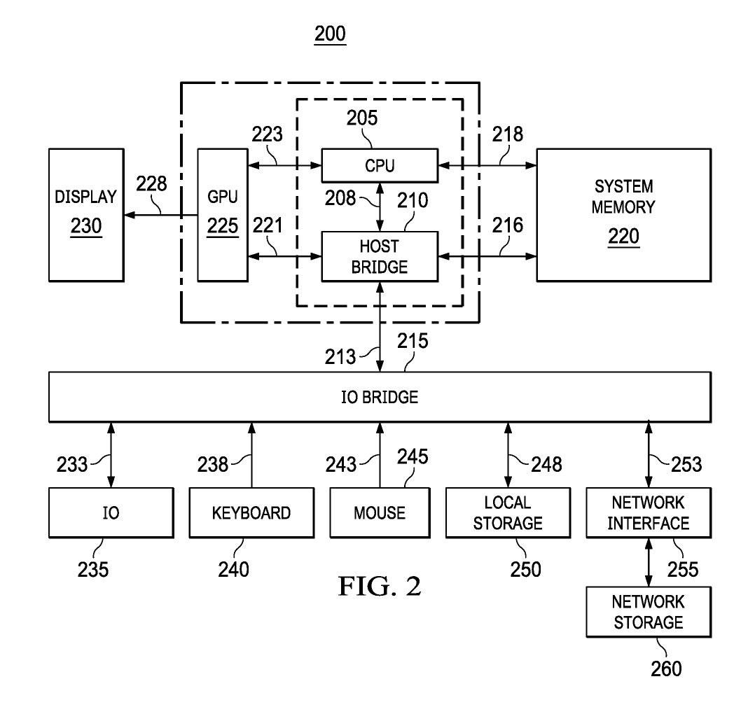

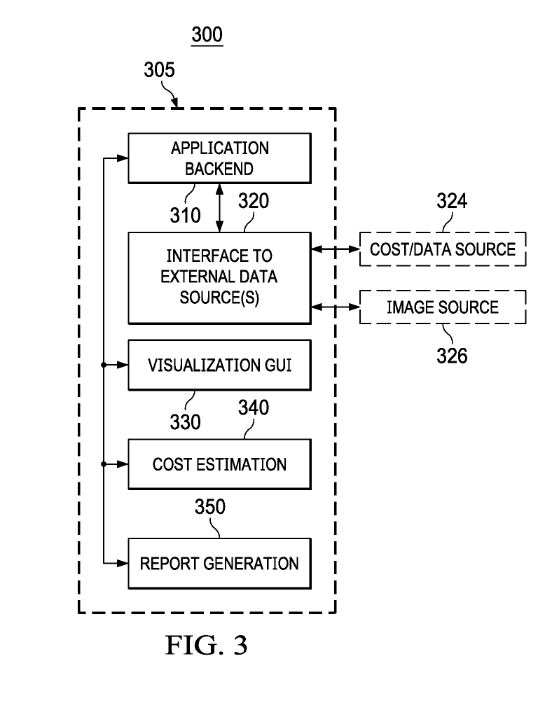

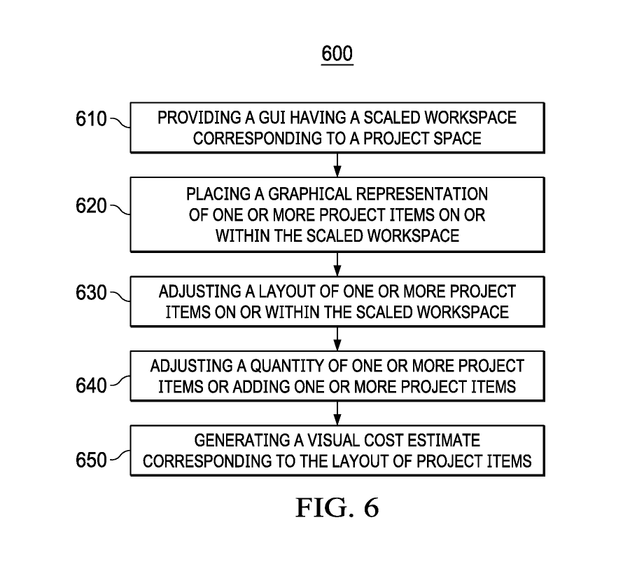

FIG. 2 shows a computing system 200 for visual cost estimating in accordance with one or more embodiments of the present invention. Computing system 200 may be configured to execute a visual cost estimating software application (e.g., 300 of FIG. 3) that performs, in whole or in part, a method of visual cost estimating (e.g., 600 of FIG. 6). Computing system 200 may include one or more central processing units (singular “CPU” or plural “CPUs”) 205, host bridge 210, input/output (“IO”) bridge 215, graphics processing units (singular “GPU” or plural “GPUs”) 225, and/or application-specific integrated circuits (singular “ASIC or plural “ASICs”) (not shown) disposed on one or more printed circuit boards (not shown) that are configured to perform computational operations. Each of the one or more CPUs 205, GPUs 225, or ASICs (not shown) may be a single-core (not independently illustrated) device or a multi-core (not independently illustrated) device. Multi-core devices typically include a plurality of cores (not shown) disposed on the same physical die (not shown) or a plurality of cores (not shown) disposed on multiple die (not shown) that are collectively disposed within the same mechanical package (not shown).

CPU 205 may be a general purpose computational device typically configured to execute software instructions. CPU 205 may include an interface 208 to host bridge 210, an interface 218 to system memory 220, and an interface 223 to one or more TO devices, such as, for example, one or more GPUs 225. GPU 225 may serve as a specialized computational device typically configured to perform graphics functions related to frame buffer manipulation. However, one of ordinary skill in the art will recognize that GPU 225 may be used to perform non-graphics related functions that are computationally intensive. In certain embodiments, GPU 225 may interface 223 directly with CPU 225 (and interface 218 with system memory 220 through CPU 205). In other embodiments, GPU 225 may interface 221 with host bridge 210 (and interface 216 or 218 with system memory 220 through host bridge 210 or CPU 205 depending on the application or design). In still other embodiments, GPU 225 may interface 233 with IO bridge 215 (and interface 216 or 218 with system memory 220 through host bridge 210 or CPU 205 depending on the application or design). The functionality of GPU 225 may be integrated, in whole or in part, with CPU 205 or host bridge 210.

Host bridge 210 may be an interface device configured to interface between the one or more computational devices and IO bridge 215 and, in some embodiments, system memory 220. Host bridge 210 may include an interface 208 to CPU 205, an interface 213 to IO bridge 215, for embodiments where CPU 205 does not include an interface 218 to system memory 220, an interface 216 to system memory 220, and for embodiments where CPU 205 does not include an integrated GPU 225 or an interface 223 to GPU 225, an interface 221 to GPU 225. The functionality of host bridge 210 may be integrated, in whole or in part, with CPU 205. TO bridge 215 may be an interface device configured to interface between the one or more computational devices and various IO devices (e.g., 240, 245) and IO expansion, or add-on, devices (not independently illustrated). IO bridge 215 may include an interface 213 to host bridge 210, one or more interfaces 233 to one or more TO expansion devices 235, an interface 238 to keyboard 240, an interface 243 to mouse 245, an interface 248 to one or more local storage devices 250, and an interface 253 to one or more network interface devices 255. The functionality of IO bridge 215 may be integrated, in whole or in part, with CPU 205 or host bridge 210. Each local storage device 250, if any, may be a non-transitory solid-state memory device, a solid-state memory device array, a hard disk drive, a hard disk drive array, or any other non-transitory computer readable medium. Network interface device 255 may provide one or more network interfaces including any network protocol suitable to facilitate networked communications.

Computing system 200 may include one or more network-attached storage devices 260 in addition to, or instead of, one or more local storage devices 250. Each network-attached storage device 260, if any, may be a non-transitory solid-state memory device, a solid-state memory device array, a hard disk drive, a hard disk drive array, or any other non-transitory computer readable medium. Network-attached storage device 260 may or may not be collocated with computing system 200 and may be accessible to computing system 200 via one or more network interfaces provided by one or more network interface devices 255.

One of ordinary skill in the art will recognize that CPU 205, host bridge 210, 10 bridge 215, GPU 225, or ASIC (not shown) or a subset, superset, or combination of functions or features thereof, may be integrated, distributed, or excluded, in whole or in part, based on an application, design, or form factor in accordance with one or more embodiments of the present invention. Thus, the description of computing system 200 is merely exemplary and not intended to limit the type, kind, or configuration of component devices that constitute a computing system 200 suitable for performing computing operations in accordance with one or more embodiments of the present invention. Additionally, one of ordinary skill in the art will recognize that computing system 200 may be a stand alone, laptop, desktop, server, blade, rack mountable, or cloud-based system and may vary based on an application or design in accordance with one or more embodiments of the present invention.

FIG. 3 shows a block diagram of a visual cost estimating software application 300 in accordance with one or more embodiments of the present invention. The software application 300 may be configured to execute on a computing system (e.g., 200 of FIG. 2) and perform, in whole, or in part, a method of visual cost estimating (e.g., 600 of FIG. 6). Visual cost estimating software application 300 may include a core feature set 305 that includes an application backend 310, an interface to external data source(s) 320, a visualization graphical user interface (“GUI”) 330, a cost estimation portion 340, and a report generation portion 350. In certain embodiments, an optional external cost and data source 324 may provide some or all cost and data (not shown) corresponding to project items (not shown). In other embodiments, equivalent cost and data (not independently illustrated) may be integrated into a database portion (not shown) of the of the application backend 310. In certain embodiments, an optional external image source 326 may provide some or all map or image data (not shown) used as part of the scaled workspace (not shown) corresponding to the project space (not shown). In other embodiments, equivalent map or image data (not shown) may be integrated into a database portion (not shown) of the application backend 310.

In operation, a user (not shown) may interact with the visualization GUI 330. The visualization GUI 330 may include a scaled workspace (not shown) that corresponds to the actual project space (not shown) where the facility is to be constructed. The scaled workspace (not shown) may comprise a two-dimensional representation of the project space (not shown) or a three-dimensional representation of the project space (not shown). In certain embodiments, the scaled workspace (not shown) may comprise a graphic representation of the project space (not shown) such as, for example, a drawing, a photograph, a satellite image, or a hybrid thereof of the project space (not shown) that may be provided by an external image source 326. In other embodiments, the scaled workspace (not shown) may comprise a three-dimensional model of the project space (not shown).

The user may generate a visual cost estimate by selecting and placing one or more project items (not shown) on or within the scaled workspace (not shown) of the visualization GUI 330. Application backend 310 may receive initial data (not shown) for one or more project items (not shown) from an external cost and data source 324 by way of interface 320, or an internal database portion (not shown) of the application backend 310. The external cost and data source 324 may provide, for example, one or more of an item name, dimensional data, safety data, cost per unit data, labor cost per unit data, and estimated time required to install data. One of ordinary skill in the art will recognize that there are a number of third-party software applications that may provide access to such data.

Application backend 310 may parse the initial data or metadata (not shown) for one or more project items (not shown) and may generate additional data or metadata related to, for example, safety spacing, ignition sources, thermal constraints, radiation distance, maintenance keep outs, connectivity information, modified footprint data, and a cost percentage of the total project. Once placed, the graphical representation of each project item (not shown) may controllably include relevant data relating to the project item (not shown) and its respective placement in relation to the project space (not shown) and other project items (not shown). For example, the user may enable or disable the display of a radiation radius of a project item that constitutes a dangerous radiation source. The user (not shown) may then adjust the layout of one or more project items (not shown) on or within the scaled workspace (not shown) according to the user's preference, one or more predetermined rules relating to one or more project items (not shown), or a relationship between two or more project items (not shown).

As the user adjusts the layout, the movement of one or more interrelated project items (not shown) may change the material and labor required to accommodate their new placement within the GUI. Application backend 310 may track all equipment, bulk material, and labor placed on or within the scaled workspace (not shown) and associated costs, including equipment, material, and labor not previously placed, but added as a result of the user's adjustment of the layout, one or more predetermined rules, or a relationship between project items. Cost estimation portion 340 may aggregate the equipment, bulk material, and labor placed in the visualization GUI 330 and generate a visual cost estimate (not shown). An optional report generation portion 350 may generate a visual cost estimate report that includes data similar to that of a conventional early phase cost estimate. One of ordinary skill in the art will recognize that the distribution of functions performed by application 300 may vary based on an application or design in accordance with one or more embodiments of the present invention.

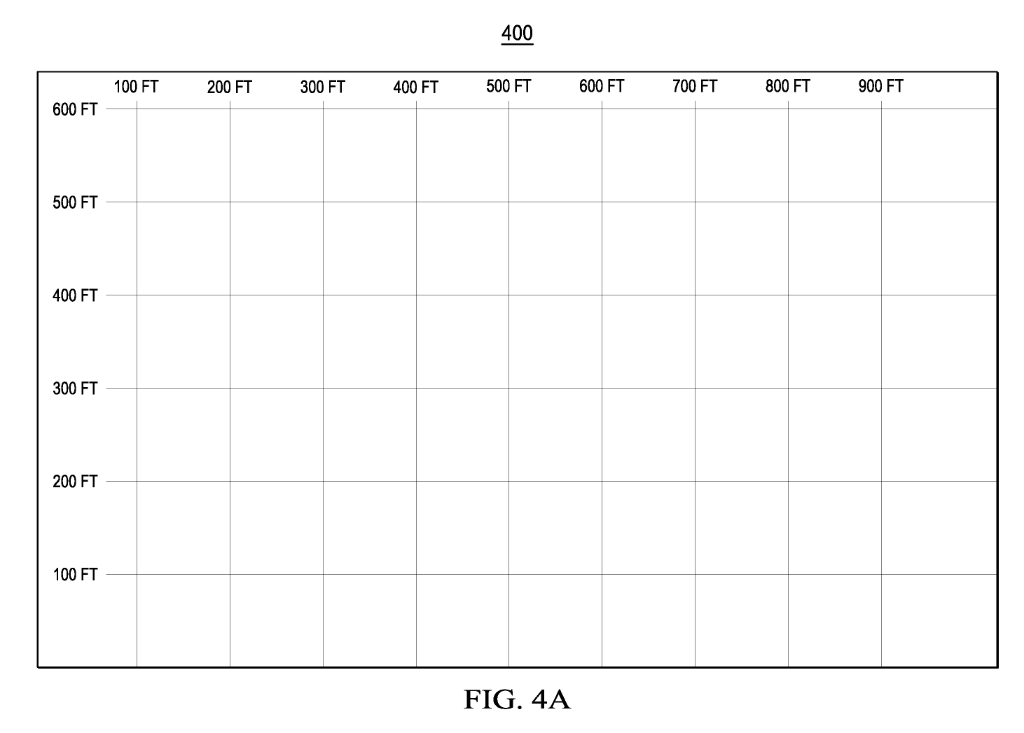

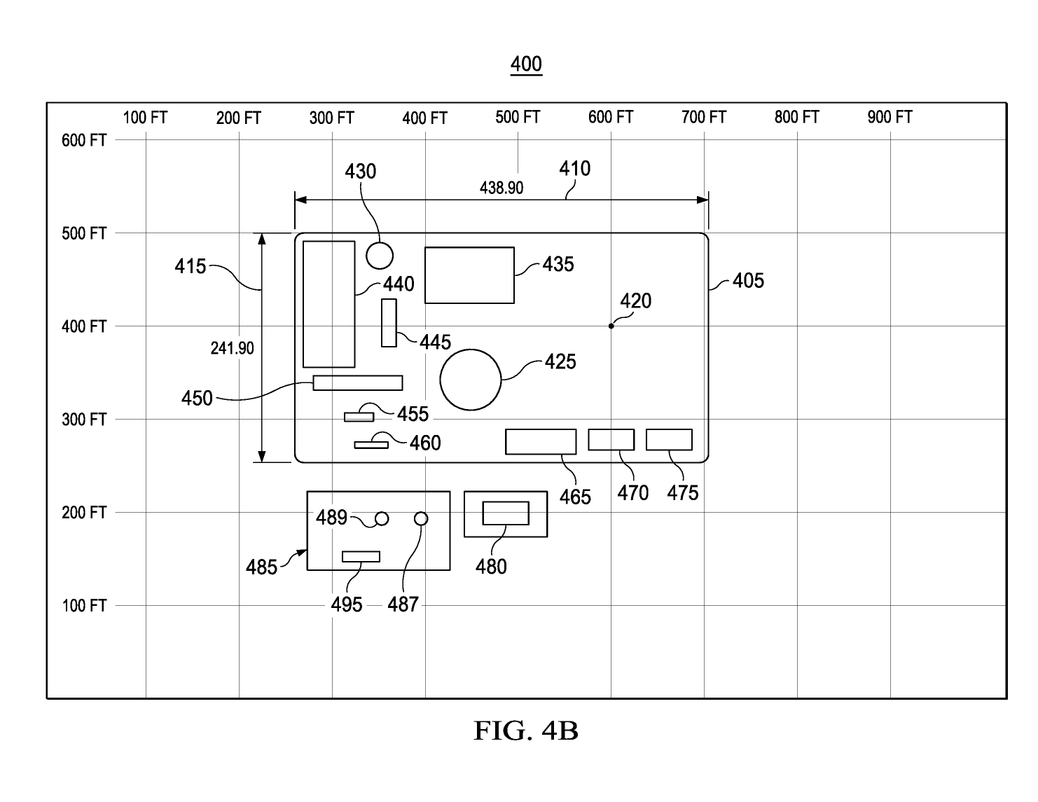

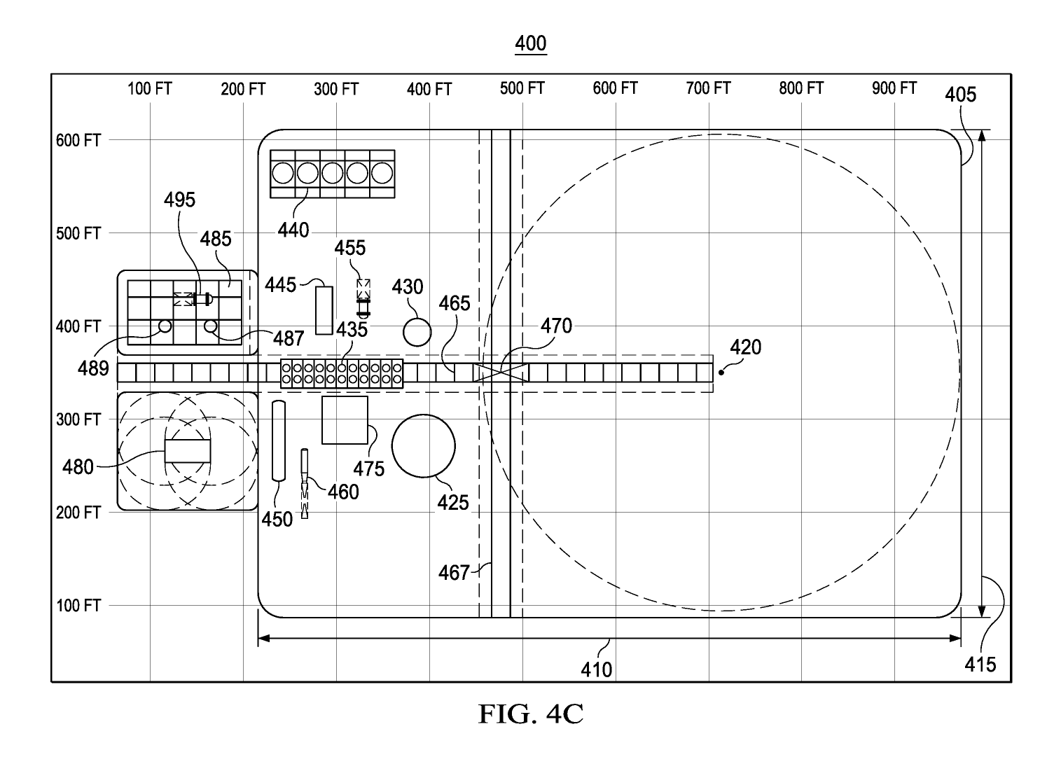

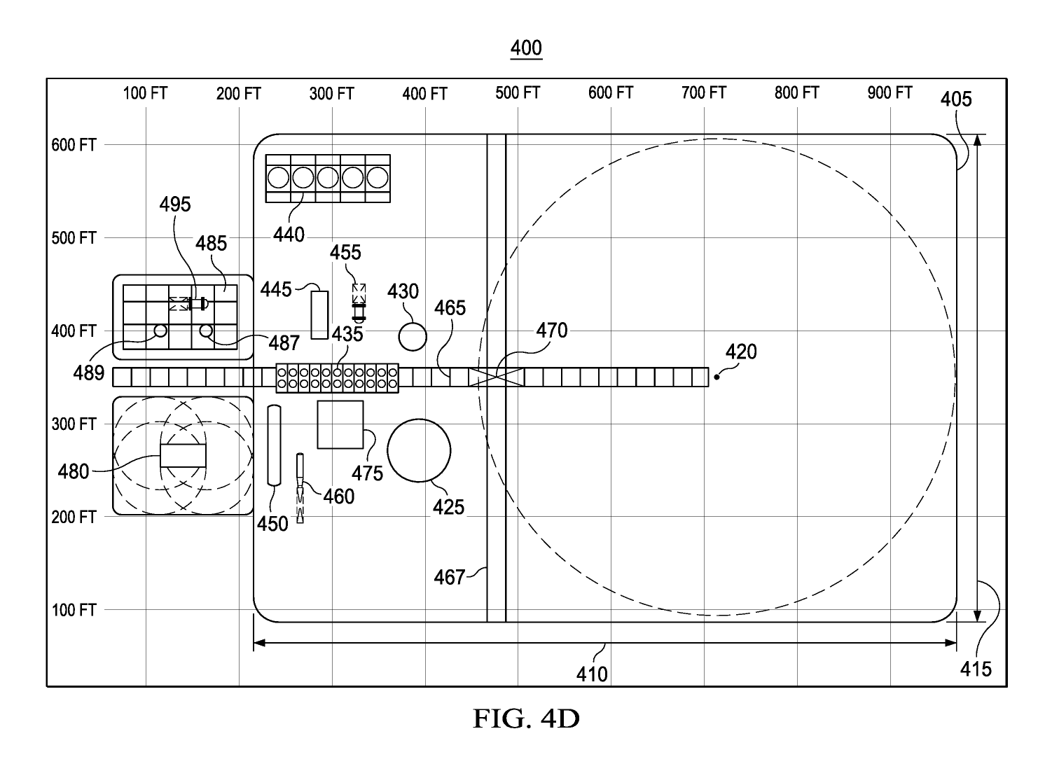

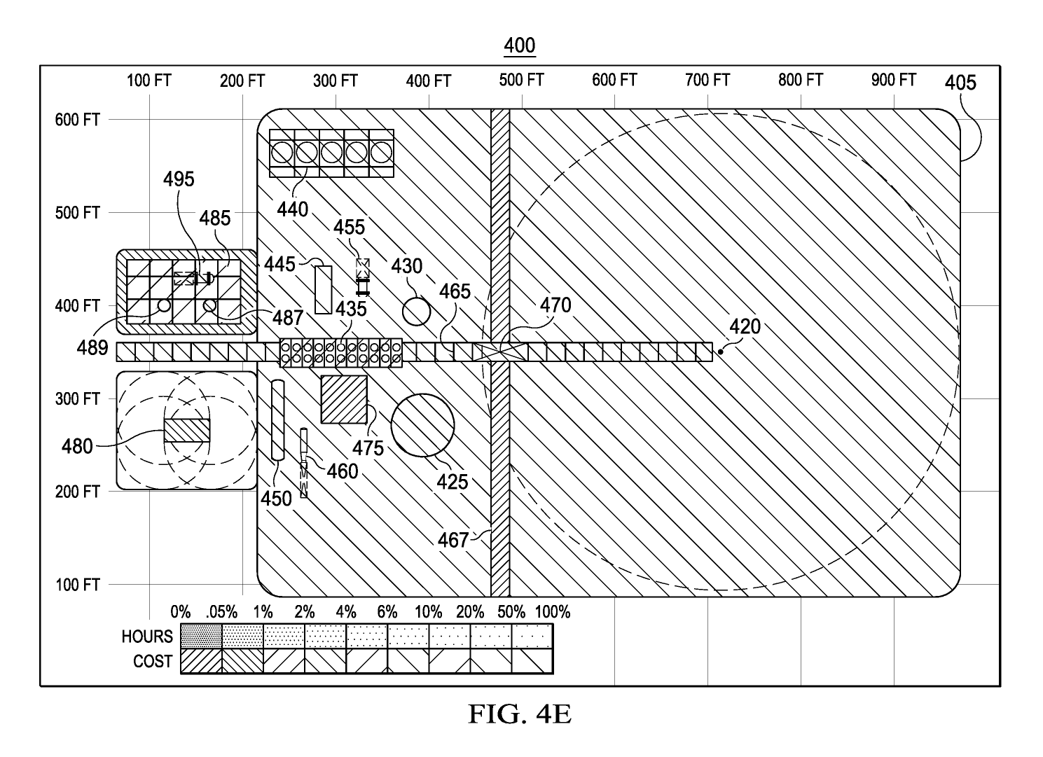

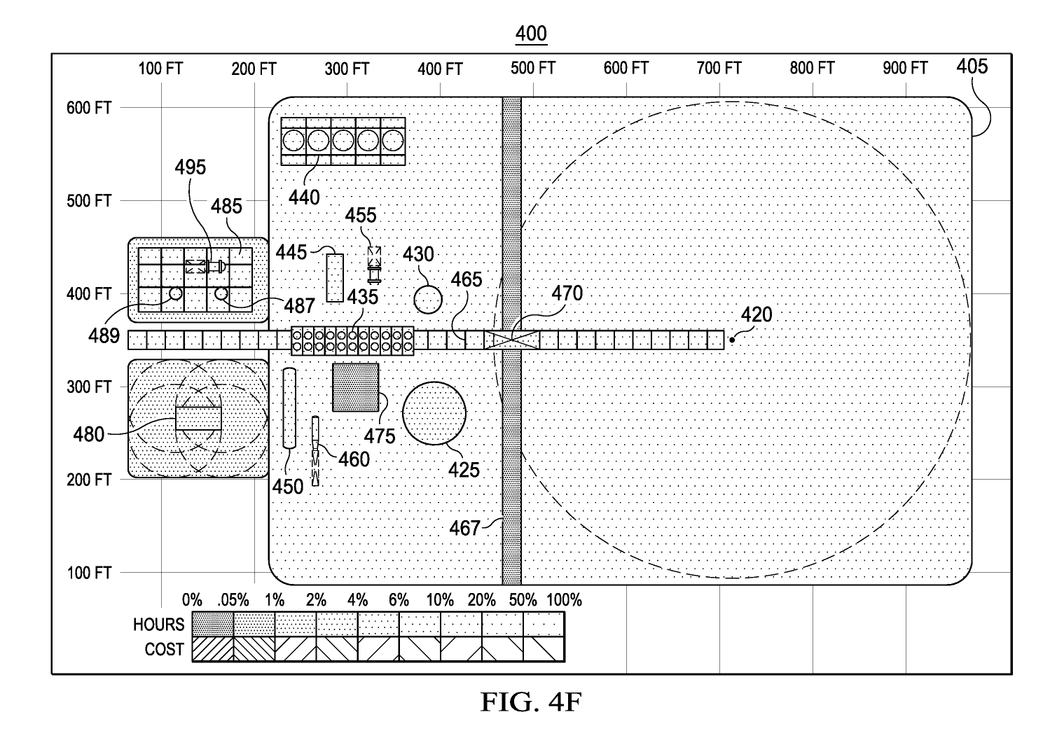

FIG. 4A shows a scaled workspace 400 corresponding to a project space (not shown) in accordance with one or more embodiments of the present invention. A visualization GUI (e.g., 330 of FIG. 3) comprises a scaled workspace 400 that may be displayed on a display device (e.g., 230 of FIG. 2) of a computing system (e.g., 200 of FIG. 2). As discussed herein, a user (not shown) may construct a visual cost estimate by placing and adjusting the layout of a representation of one or more project items (not shown) on or within the scaled workspace 400 of the visualization GUI (e.g., 330 of FIG. 3). In certain embodiments, the scaled workspace 400 may comprise a two-dimensional representation (as shown in FIG. 4A) of the actual project space (not shown), having dimensions of length and width, where the facility is to be constructed. The representations (not shown) of one or more project items (not shown) placed on the scaled workspace (not shown) may also be two-dimensional, also having dimensions of length and width. In other embodiments, the scaled workspace 400 may comprise a three-dimensional representation (not shown) of the actual project space (not shown), having dimensions of length, width, and height. The three-dimensional representation (not shown) may be a model (not shown) that includes one or more floors, walls, ceilings, and support structures (not shown). The representations (not shown) of one or more project items (not shown) placed within the scaled workspace (not shown) may also be three-dimensional, having dimensions of length, width, and height. In this way, the user may place three-dimensional representations of one or more project items (not shown) within the three-dimensional scaled workspace (not shown) and ensure dimensional fit while accurately reflecting costs driven by the layout in three-dimensions. Notwithstanding the above, in certain embodiments, including embodiments where the scaled workspace is represented in two-dimensions or three-dimensions (not shown), the representation of one or more project items (not shown) may include dimensional data related to height that may be used as part of the placement and adjustment of the layout or related cost drivers related to height.

One of ordinary skill in the art will recognize that scaled workspace 400 may be scaled dimensionally to accommodate the representation of the actual project space for the intended facility and may vary based on an application or design in accordance with one or more embodiments of the present invention.

Continuing, FIG. 4B shows a graphical representation of one or more project items placed on the scaled workspace 400 in accordance with one or more embodiments of the present invention. The visualization GUI (e.g., 330 of FIG. 3) of the software application (e.g., 300 of FIG. 3) may include a project item menu or ribbon (not shown) that allows the user (not shown) to quickly and easily select one or more project items for rough placement on or within the scaled workspace 400. When the user (not shown) selects a specific project item, such as, for example, a specific type and kind of flare device, the external cost and data source (e.g., 324 of FIG. 3), or a corresponding integrated database within the software application (e.g., 300 of FIG. 3), may provide initial data or metadata corresponding to one or more of an item name, an item description, an x-dimension, a y-dimension, a cost per unit, a labor per unit, and an estimated time to install. One of ordinary skill in the art will recognize that the initial data or metadata provided may vary based on the type or kind of third-party external cost and data source used or the content of an integrated database.

For purposes of initial placement, the x-dimension and the y-dimension provided by the external cost and data source (e.g., 324 of FIG. 3), or corresponding integrated database within the software application (e.g., 300 of FIG. 3), may be used to scale the representation of the project item on or within the scaled workspace 400. In addition, the data or metadata corresponding to the placed project item may be brought into an internal database portion of the software application (e.g., 300 of FIG. 3) and tracked for purposes of generating a visual cost estimate as described in more detail herein.

As shown in FIG. 4B, the user has placed as plurality of project items on the scaled workspace 400 for an exemplary process plant including, for example, flare 420, tank 425, double diameter tower 430, air cooler 435, cooling tower 440, compressor 445, horizontal tank 450, TEMA heat exchanger 455, re-boiler 460, pipe rack 465, road 467, road crossing 470, vessel 475, building 480, process area 485, tower 487, pressure vessel 489, and shell and tube heat exchanger 495. One of ordinary skill in the art will recognize that the above-noted list of project items is merely exemplary of the type or kind of project items that may be found in a midstream or downstream process plant in the oil and gas industry.

It is important to recognize that, for purposes of illustration only, the exemplary scaled workspace 400 includes area 405 and the area (not measured) of adjacent building 480 and processing area 485. Area 405 has an initial length of 438.90 feet and an initial width of 241.90 feet based on the initial dimensional data provided by the external cost and data source (e.g., 324 of FIG. 3) or corresponding integrated database within the software application (e.g., 300 of FIG. 3). If an early phase cost estimate was generated at this point in the layout of the one or more project items on or within the scaled workspace 400, the cost estimate would correspond to the conventional early phase cost estimate reflected by FIG. 1.

Continuing, FIG. 4C shows an adjusted layout of one or more project items on the scaled workspace 400 according to a user's preference, one or more predetermined rules relating to one or more project items, or a relationship between two or more project items in accordance with one or more embodiments of the present invention.

As noted above, the scaled representations of the one or more project items placed on the scaled workspace 400 may be dimensionally scaled based on the x-dimension and the y-dimension data provided by the external cost and data source (e.g., 324 of FIG. 3) or a corresponding integrated database within the software application (e.g., 300 of FIG. 3). However, the software application (e.g., 300 of FIG. 3) may generate additional data or metadata for one or more of the project items based on the initial data or metadata previously obtained and/or newly obtained additional data or metadata from an internal database (not shown) or third-party sources (not shown).

For purposes of example, the software application (e.g., 300 of FIG. 3) may validate the dimensional data parsed from the initial data or metadata for a given project item against an internal database (not shown) of the application (e.g., 300 of FIG. 3) or another third-party cost and data source (e.g., 324 of FIG. 3). Additional data or metadata may also be generated by the software application (e.g., 300 of FIG. 3) such as, for example, true footprint, boundary, safety, ignition, maintenance, and other spacing or keep out areas obtained from third-party sources (not shown) or an internal database (not shown). In one or more embodiments of the present invention, additional data or metadata obtained or generated may include one or more of, but is not limited to, true footprint, boundary, safety, ignition, maintenance, and radiation spacing or keep out areas and additional dimensional data such as, for example, height.

The software application (e.g., 300 of FIG. 3) may use some or all of the additional data or metadata, such as, for example, true footprint, boundary, safety, ignition, maintenance, and radiation spacing or keep out areas and additional dimensional data such as, for example, height to controllably modify the representation of one or more project items. The user may controllably modify the representations by enabling or disabling the inclusion of certain additional data or metadata. For example, flare 420, a specific type of flare device, includes in FIG. 4C a radiation circle that represents the area around flare 420 that should be treated as a safety keep out area where people and equipment that are susceptible to injury or damage should not be located. Certain project items, such as, for example, TEMA heat exchanger 455, re-boiler 460, and shell and tube heat exchanger 495 may include a maintenance keep out area represented by an X'd out box that must remain fully accessible to allow for maintenance of the respective equipment. Certain project items, such as, for example, building 480 may include ignition area keep outs represented by dashed circles that represent the area where equipment and material that are potentially ignitable cannot be placed due to the presence of ignition sources. Certain project items, such as, for example, pipe rack 465, road 467, and road crossing 470 may include safety, boundary, or keep out areas represented by dotted lines. One of ordinary skill in the art will recognize that the above-noted user controllable modifications to the representations of one or more project items are merely exemplary and additional data or metadata, and corresponding modifications to the representations, may be used in accordance with one or more embodiments of the present invention.

In certain embodiments, the layout of one or more project items may be adjusted based on a user preference. The user preference may be informed, in part, by the additional data or metadata shown on the scaled workspace 400. For example, flare 420 may be moved to be free and clear of other project items that were previously within what is now known to be its radiation safety area. In certain embodiments, the layout of one or more project items may be adjusted based on one or more predetermined rules relating to one or more project items. The one or more predetermined rules may represent a knowledge base about various project items and their interactions. For example, ignition sources may be kept away from flammable material. The software application (e.g., 300 of FIG. 3) may automatically move adjacent ignition sources and flammable material or alert the user to the fact that these project items must be separated. The one or more predetermined rules may ensure that boundary, safety, ignition, maintenance, and radiation spacing or keep out areas are enforced or alert the user to the fact that certain project items require further adjustment to their layout. In certain embodiments, the layout of one or more project items may be adjusted based on a relationship between two or more project items. The relationship between two or more project items may represent a knowledge base of relationships between various project items and their interactions. For example, a pipe (not shown) may provide flammable material (not shown) to a flare (not shown) for burning off. As such, the pipe (not shown) and flare (not shown) must be placed in a feasible manner that permits their connectivity driven by the process flow. One of ordinary skill in the art will recognize that the one or more predetermined rules and the relationships between two or more project items may vary based on an application or design and is not limited to the above-noted examples. Additionally, one of ordinary skill in the art will recognize that the one or more predetermined rules and the relationships between two or more project items may be used to interactively alert the user to adjust the layout or to automatically adjust the layout in accordance with the predetermine rules or relationships.

Returning to the figure, the layout of one or more project items may be adjusted as discussed above to arrive at the depicted exemplary layout. It is important to note that a quantity of one or more project items previously placed may be adjusted based on the layout of one or more project items on or within the scaled workspace. For example, pipe rack 465 may be extended to provide the necessary connectivity to flare 420, which results in a substantial increase in the quantity and associated cost of pipe rack 465, bulk materials (not shown), and labor (not shown). The software application (e.g., 300 of FIG. 3) tracks and updates its internal record for the material and labor costs that are used to generate the visual cost estimate as discussed herein. In this way, the user (not shown) may define the scope of the project visually in a familiar facilities layout environment by placing and interactively or automatically adjusting the layout of the representations of one or more project items on or within the scaled workspace 400 in a feasible manner that considers the exigencies of the actual project space, the type or kind of equipment used, and the relationships between them.

Continuing, FIG. 4D shows a final layout of one or more project items on the scaled workspace 400 according to one or more embodiments of the present invention. In the exemplary final layout depicted, various spacings and keep outs may be controllably disabled, such as, for example, the boundary (not shown) of road 467 of FIG. 4C may be turned off as shown in FIG. 4D. However, some critically important spacings and keep outs may be displayed, such as, for example, radiation distances for flare 420, ignition source keep outs for building 480, and maintenance keep outs for re-boiler 460, TEMA heat exchanger 455, and shell and tube heat exchanger 495.

As discussed above, by adjusting the layout, various project items may be moved on or within the scaled workspace 400. The quantities of various equipment may be adjusted accordingly. For example, the movement of flare 420 may require an increase in the number of pipe racks 465, supporting structures, and bulk materials and associated labor. One of ordinary skill in the art will recognize that such quantities may be adjusted up or down depending on the application or design. New equipment or bulk material, and associated labor, not previously placed, may be added to the layout, driven by the adjustment of one or more project items previously placed. For example, by layout, pipe rack 465 must cross road 467. As such, the layout forces the addition of equipment, supporting structures, and bulk material as well as labor that allows a portion of pipe rack 467 to be disposed higher than a predetermined clearance of road 467. It is important to note that this additional equipment, supporting structure, and bulk material were not originally contemplated and would not have been included in a conventional early phase cost estimate, but were added to the layout by the software application (e.g., 300 of FIG. 3) because of the adjusted layout. As such, in one or more embodiments of the present invention, an important aspect of software application (e.g., 300 of FIG. 3), especially in the context of process plant facilities in the oil and gas industry, is the connectivity between one or more project items and their interaction with the project space. Once the one or more project items have been placed and the layout adjusted, a final layout of one or more project items, supporting structures, and bulk material as well as labor may be used to generate the visual cost estimate. By integrating process layout, connectivity, and early phase cost estimating, a visual cost estimate may be prepared, much earlier in the process, which is substantially more accurate than conventional early phase cost estimates.

It is important to note that the footprint for area 405 is now approximately 900 feet in the x-dimension 410 and approximately 520 feet in the y-dimension 415, substantially larger than that indicated by the rough placement of FIG. 4B, which represents a substantial improvement in the accuracy of associated costs.

Continuing, FIG. 4E shows a visual depiction of a distribution of cost for material costs corresponding to the layout of one or more project items on the scaled workspace 400 in accordance with one or more embodiments of the present invention. For each project item placed, one or more of equipment cost, supporting structure cost, and bulk material cost for that particular project item is calculated (e.g., 340 of FIG. 3) by the software application (e.g., 300 of FIG. 3) as part of generating (e.g., 350 of FIG. 3) the visual cost estimate. The visual cost estimate generated may be a traditional spreadsheet (e.g., FIG. 6) or a visual depiction of costs integrated with the display of the layout of one or more project items on or within the scaled workspace 400. The calculated total material cost for each project item may be displayed on the scaled workspace 400 in a manner that conveys the distribution of costs. In certain embodiments, the visual depiction may be a heatmap that includes a color scale (not shown) visually showing the concentration of material cost within the layout. In other embodiments, the visual depiction may be a heatmap that includes a black and white scale visually showing the concentration of material cost within the layout. One of ordinary skill in the art will recognize that other visual depictions of the distribution of costs may be used in accordance with one or more embodiments of the present invention.

Continuing, FIG. 4F shows a visual depiction of a distribution of cost for labor costs corresponding to the layout of one or more project items on the scaled workspace 400 in accordance with one or more embodiments of the present invention. Similar to the material costs discussed above with respect to FIG. 4E, for each project item placed, the labor cost for that particular project item may be calculated (e.g., 340 of FIG. 3) by the software application (e.g., 300 of FIG. 3) as part of generating (e.g., 350 of FIG. 3) the visual cost estimate. The visual cost estimate generated may be a traditional spreadsheet (e.g., FIG. 6) or a visual depiction of costs integrated with the display of the layout of one or more project items on or within the scaled workspace 400. The calculated labor cost for each project item may be displayed on the scaled workspace 400 in a manner that conveys the distribution of costs. In certain embodiments, the visual depiction may be a heatmap that includes a color scale (not shown) visually showing the concentration of labor cost within the layout. In other embodiments, the visual depiction may be a heatmap that includes a black and white scale visually showing the concentration of labor cost within the layout. One of ordinary skill in the art will recognize that other visual depictions of the distribution of costs may be used in accordance with one or more embodiments of the present invention.

Additionally, one of ordinary skill in the art will recognize that a visual depiction of total cost, including both material and labor, may be generated in a similar manner as discussed above in accordance with one or more embodiments of the present invention. The total cost may be displayed in the aggregate or through the use of different scales such that both material and labor costs are shown, but independently evaluated in a visual manner.

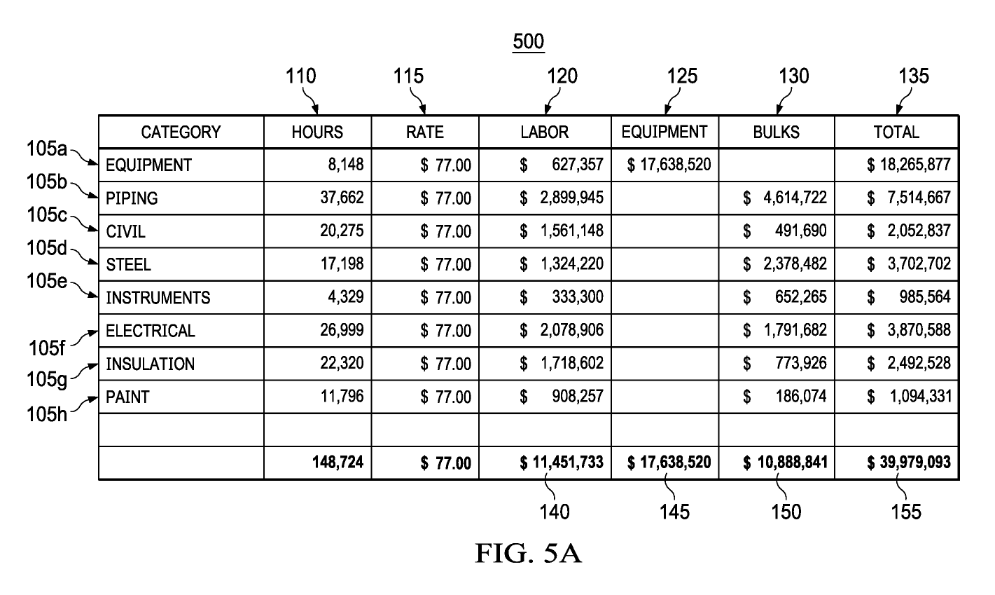

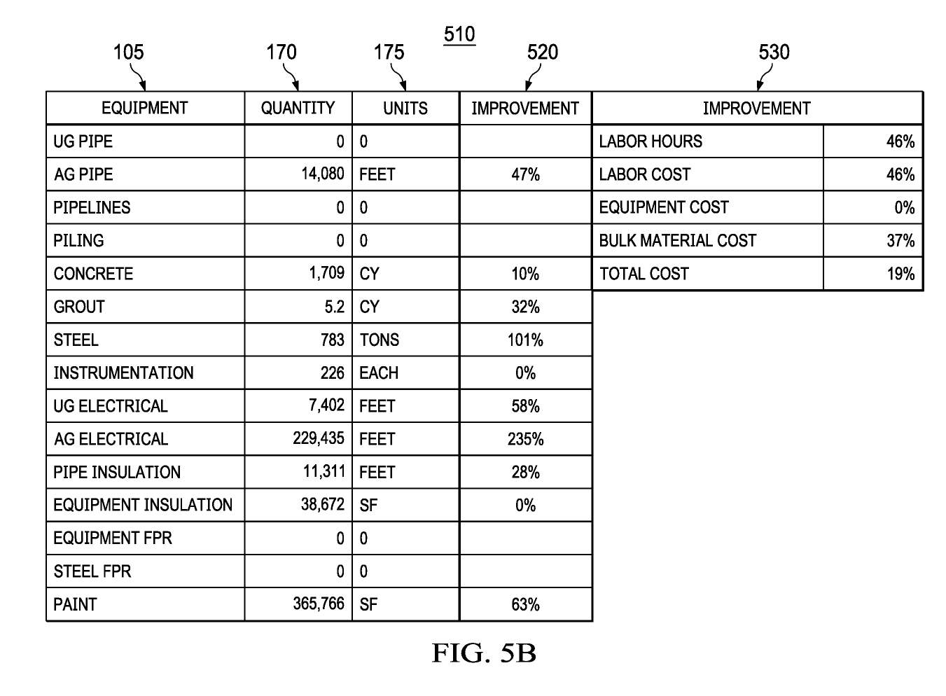

FIG. 5A shows a visual cost estimate 500 for a complex capital project in accordance with one or more embodiments of the present invention. Once the layout is finalized, the software application (e.g., 300 of FIG. 3) may use the layout to generate a visual cost estimate 500. Similar to the conventional early phase cost estimate of FIG. 1A, the visual cost estimate 500 may be an itemized list of costs. The visual cost estimate 500 depicted in FIG. 5A may include, from top to bottom, a plurality of categorical line items 105a through 105h, where each line item extends across the page horizontally and corresponds to estimated costs associated with that category. Within each categorical line item 105, the hours 110 represents an estimate of the number of hours of labor required for that category, the hourly rate 115 represents the hourly rate for labor, and the labor cost 120 may be calculated by multiplying the number of hours 110 by the hourly rate 115 and represents the estimated labor cost for the respective category. The equipment cost 125 represents an estimate of equipment cost for the respective category and the bulk cost 130 represents the cost of all other supporting structure and bulk materials required for that category. Visual cost estimate 500 may include a categorical line item sub-total 135, a sub-total of labor cost 140, a sub-total of equipment cost 145, a sub-total of bulk cost 150, and a total early phase cost estimate 155.

While the visual cost estimate 500 depicted in FIG. 5A is a summary, each categorical line item 105 may correspond to an itemized list within that category (not independently illustrated) that is summarized within its respective categorical line item 105. For example, the categorical line item entry for equipment 105a as depicted in FIG. 5A may correspond to an itemized list of various equipment (not independently illustrated) that is summarized within the categorical line item 105a. In certain embodiments, the categorical line item 105 may be expanded to show the itemized list (not shown) within that category. For complex capital projects in the oil and gas industry, the expanded visual cost estimate (not shown) may be many thousands of lines long (not shown) and consolidated and summarized as presented in FIG. 5A.

It is important to recognize that, for the exemplar complex capital project discussed above with respect to FIG. 1 through 5, the total visual cost estimate 155 of FIG. 5A, encompassing equipment, labor, and bulk material, is $39,979,093, which is approximately 19% higher than the total conventional early phase cost estimate (155 of FIG. 1) of FIG. 1 of $33,479,773. The improvement in the accuracy of the visual cost estimate is attributable to additional costs added into the cost estimate, driven by the layout of one or more project items on or within the scaled workspace (e.g., 400 of FIG. 4).

Continuing, FIG. 5B shows an exemplary itemized list 510 of equipment 105a and bulk material of the complex capital project in accordance with one or more embodiments of the present invention. As discussed above, the categorical line item 105a for equipment shown in FIG. 5A may represent a summary of an itemized list of equipment that was not shown in the summary view of FIG. 5A. In certain embodiments, as shown in FIG. 5B, the itemized list 510 may include a column showing a type of equipment 105, a column showing its respective quantity 170, and a column showing units 175. One of ordinary skill in the art will recognize that the itemized list 510 is merely exemplary and may include other information not shown such as, for example, cost and a sub-total for each respective type of equipment 105 in accordance with one or more embodiments of the present invention. For purposes of illustration only, itemized list 510 shows improvements 520 in the estimate for the respective type of equipment 105a. In this context, improvement means adjustment to the cost estimate of the corresponding conventional early phase cost estimate of FIGS. 1A and 1B. As shown in the figure, the estimate of AG pipe, steel, UG electrical, AG electrical, and paint were improved by 47%, 101%, 58%, 235%, and 63% respectively over that of the conventional early phase cost estimate of FIG. 1B. Collectively, as shown in column 530, the estimate of labor hours was improved by 46%, the estimate of labor cost was improved by 46%, the cost of bulk materials was improved by 37% and the total cost estimate generated by a method of visual cost estimating represents a 19% improvement over that of a conventional early phase cost estimate. One of ordinary skill in the art will recognize that the complex capital project discussed with respect to FIGS. 1 through 5 is merely exemplary and may apply to any complex capital project in accordance with one or more embodiments of the present invention.

FIG. 6 shows a method of visual cost estimating 600 in accordance with one or more embodiments of the present invention. As discussed above, in one or more embodiments of the present invention, a method of visual cost estimating 600 may be performed, in whole or in part, by a software application (e.g., 300 of FIG. 3) configured to execute on a computing system (e.g., 200 of FIG. 2).

In step 610, a software application may provide a GUI displayed on a display device of a computing system comprising a scaled workspace corresponding to a project space. The scaled workspace may be a scaled reproduction of an actual project space where a facility is to be constructed. In certain embodiments, the scaled workspace may comprise a two-dimensional representation of the project space. In other embodiments, the scaled workspace may comprise a three-dimensional representation or three-dimensional model of the project space. In still other embodiments, the scaled workspace may comprise a hybrid two-dimensional representation of the project space that includes data or metadata relating to, for example, height or vertical clearances. In certain embodiments, the scaled workspace may comprise a graphic representation of the project space such as, for example, a drawing, a photograph, a satellite image, or a hybrid of the project space that may be provided by an external image source or an integrated database of the software application. In operation, a user may interact with the GUI and generate a visual cost estimate.

In step 620, the user may place a graphical representation of one or more project items on or within the scaled workspace. The software application may receive initial data for one or more project items from an external cost and data source or an internal database portion of the software application. The external cost and data source may provide, for example, one or more of an item name, dimensional data, safety data, cost per unit data, labor cost per unit data, and estimated time required to install data. The initial data may be data or metadata and may be tracked and stored by the software application for each and every project item that is placed on or within the scaled workspace. The software application may parse the initial data or metadata and may obtain or generate additional data or metadata as well. The additional data or metadata generated may include safety spacing data, ignition source (safe radius) data, thermal constraint data, radiation distance data, maintenance keep out data, connectivity data, modified footprint data, and cost percentage data as percentage of a total cost estimate. Once placed, the graphical representation of each project item may controllably include and display relevant data relating to the project item and its respective placement in relation to the project space and other project items. For example, the user may enable or disable the display of a radiation radius of a project item that constitutes a dangerous radiation source. With respect to each and every project item placed on or within the scaled workspace, the software application may track all associated equipment, bulk material, and labor costs, which will be used as part of generating a visual cost estimate.

In step 630, the layout of one or more project items on or within the scaled workspace may be adjusted. In certain embodiments, the adjustment of the layout may comprise adjusting a position of one or more project items represented on the scaled workspace. In other embodiments, the adjustment of the layout may comprise adjusting a position of one or more project items within the scaled workspace in three-dimensions.

In certain embodiments, a user may adjust the layout based on a user's preference. In other embodiments, the software application may adjust the layout based on one or more predetermined rules relating to one or more project items or a relationship between two or more project items. In still other embodiments, the software application make alert and suggest that the user adjust the layout based on one or more predetermined rules relating to one or more project items or a relationship between two or more project items.

The one or more predetermined rules may represent an application-specific knowledge base about various project items and their interactions. For example, in the context of process plants, an exemplary predetermined rule may be that ignition sources cannot be within a certain distance of flammable material. In certain embodiments, the software application may automatically adjust the layout by moving adjacent ignition sources and flammable material. In other embodiments, the software application may alert a user to the fact that these project items must be separated. The one or more predetermined rules may ensure that boundary, safety, ignition, maintenance, and radiation spacing or keep out areas are enforced or alert the user to the fact that certain project items require further adjustment to their layout.

Similarly, the relationship between two or more project items may represent an application specific knowledge base of relationships between various project items, their interactions, and optionally their interactions with the project space. For example, in the context of process plant, an exemplary relationship may recognize that a pipe provides flammable material to a flare for burning off. As such, the pipe and the flare must be placed in a feasible manner that permits their connectivity driven by the process flow. One of ordinary skill in the art will recognize that the one or more predetermined rules and the relationships between two or more project items may vary based on an application or design and is not limited to the above-noted examples.

In step 640, a quantity of one or more project items previously placed may be adjusted based on the layout of one or more project items on or within the scaled workspace or one or more project items may be added based on the layout of one or more project items previously placed or the relationship between two or more project items previously placed. For example, in the context of process plants, a pipe rack may be extended to provide the necessary connectivity to a flare, which may result in a substantial increase in the quantity and associated cost of the pipe rack, supporting structure, bulk material, and labor cost. The software application may track and update its internal record for the bill of materials that is used to generate a visual cost estimate as discussed herein. In this way, the user may define the scope of the project visually in a familiar facilities layout environment by placing and interactively or automatically adjusting the layout of the representations of one or more project items on or within the scaled workspace in a feasible manner that considers the exigencies of the actual project space, the type or kind of equipment used, and the relationships between them. The software application may adjust the equipment, bulk material, and labor costs for one or more project items corresponding to the present layout which will be used to generate the visual cost estimate.

In step 650, a visual cost estimate corresponding to the layout of project items on or within the scaled workspace may be generated. In certain embodiments, the software application may generate a bill of materials cost estimate and a labor cost estimate based on the layout of one or more project items on or within the scaled workspace. The bill of material cost estimate may be a total cost of equipment, supporting structure, and bulk material cost for all categorical items of equipment placed on or within the scaled workspace. Similarly, the labor cost estimate may be a total cost of the labor associated with all categorical items of equipment placed on or within the scaled workspace. As discussed above, a project item cost as a percentage of total cost may be calculated. A material cost may be distinguished from a labor cost. As such, a material cost of a project item as a percentage of total material cost or total cost for the project may be calculated. Similarly, a labor cost of a project item as a percentage of total labor cost or total cost of the project may be calculated.

In certain embodiments, the visual cost estimate generated may be a traditional spreadsheet or a visual depiction of costs integrated with the display of the layout of one or more project items on or within the scaled workspace. The calculated total material cost for each project item may be displayed on the scaled workspace in a manner that conveys the distribution of costs. In certain embodiments, the visual depiction may be a heatmap that includes a color scale visually showing the concentration of material cost within the layout. In other embodiments, the visual depiction may be a heatmap that includes a black and white scale visually showing the concentration of material cost within the layout. One of ordinary skill in the art will recognize that other visual depictions of the distribution of costs may be used in accordance with one or more embodiments of the present invention.

A visual depiction of a distribution of material and labor costs corresponding to the layout of project items on or within the scaled workspace provides visual focus on the actual cost drivers of the project. Advantageously, the visual cost estimate allows interested parties to visualize the layout of the facility and the associated cost drivers, facilitates communication of project scope and cost, and simplifies project review and management. In addition, alternate layout scenarios, and their cost impact, may be visually evaluated for budgetary and feasibility determinations.

One of ordinary skill in the art will recognize that a non-transitory medium comprising software instructions may, when executed by a processor, perform a method of visual cost estimating in accordance of one or more embodiments of the present invention.

Advantages of one or more embodiments of the present invention may include one or more of the following:

In one or more embodiments of the present invention, a method of visual cost estimating provides an early phase cost estimate based on a visual layout of project items on or within a scaled workspace corresponding to a project workspace that is substantially more accurate than conventional cost estimates.

In one or more embodiments of the present invention, a method of visual cost estimating provides an early phase cost estimate that is more closely aligned to the actual project space where the facility is to be constructed. Conventional methods of early phase cost estimating are completely disconnected from, and typically have no relation to, the actual project space or its layout. As a consequence, conventional cost estimates tend to substantially underestimate required equipment and labor, resulting in project creep and cost overruns that are typically not identified until later detailed phases of the project or during actual construction. These cost overruns tend to be multiples of the conventional early phase cost estimate, and, in some instances, render the project economically impracticable.

In one or more embodiments of the present invention, a method of visual cost estimating provides an early phase cost estimate based on a visual layout of project items on or within a scaled workspace corresponding to a project workspace that improves the constructability of the project over conventional cost estimates.

In one or more embodiments of the present invention, a method of visual cost estimating provides an early phase cost estimate that is more closely aligned to the actual project space where the facility is to be constructed. Conventional methods of early phase cost estimating are completely disconnected from, and typically have no relation to, the actual project space or its layout. As a consequence, conventional cost estimates may not include necessary equipment or labor and tend to have constructability issues. When these issues arise, construction is typically stopped, the layout and design is revisited, and the project management timeline is blown out. In some instances, these constructability issues and delays render the project infeasible.

In one or more embodiments of the present invention, a method of visual cost estimating visually adjusts the layout of project items on or within the scaled workspace based on a user's preference, one or more predetermined rules relating to one or more project items, or a relationship between two or more project items. The predetermined rules and relationships between project items may provide visual clues as to where project items may be placed within the scaled workspace and adjust a quantity of one or more project items previously placed or add one or more project items as needed based on the adjusted layout. As the knowledge base for facilities layout and capital cost estimating are becoming scarce in the industry, this visually driven approach simplifies the early phase cost estimating process, thereby allowing the new generation of professionals to come up to speed more quickly and be more proficient in their work.

In one or more embodiments of the present invention, a method of visual cost estimating provides a visual layout that is a representation of a two-dimensional scaled workspace or a three-dimensional scaled workspace model. In two-dimensional embodiments, the layout of project items may be adjusted in two-dimensions on the scaled workspace. In three-dimensional embodiments, the layout of project items may be adjusted in three-dimensions within the scaled workspace.

In one or more embodiments of the present invention, a method of visual cost estimating provides a visual depiction of a distribution of cost for the bill of materials corresponding to the layout of the project items on or within the scaled workspace. The heat mapping provides visual focus on the drivers of material cost within the project.

In one or more embodiments of the present invention, a method of visual cost estimating provides a visual depiction of a distribution of cost for labor corresponding to the layout of the project items on or within the scaled workspace. The heat mapping provides visual focus on the drivers of labor cost within the project.

In one or more embodiments of the present invention, a method of visual cost estimating allows a user to define the scope of a project visually, in a familiar facilities layout environment, by placing and interactively adjusting the layout of a representation of one or more project items on or within the scaled workspace.

In one or more embodiments of the present invention, a method of visual cost estimating provides a more accurate cost estimate, earlier in the process, by reflecting cost differentials corresponding to constraints imposed by the actual project space, constraints imposed by the project items, or the relationship between project items or project items and the project space. In addition, the visual cost estimate may be easily updated to reflect engineering changes, the movement of equipment, and the addition or subtraction of equipment.

In one or more embodiments of the present invention, a method of visual cost estimating allows interested parties to visualize the layout of the facility and the associated cost drivers, facilitates communication of project scope and cost, and simplifies project reviews. In addition, alternate layout scenarios, and their cost impact, may be more easily evaluated for economic feasibility.

In one or more embodiments of the present invention, a method of visual cost estimating reduces project creep, improves constructability, and improves project management over conventional methods of early phase cost estimating.

In one or more embodiments of the present invention, a method of visual cost estimating provides an integrated early phase cost estimating and planning solution that addresses a long felt and unsolved need in the industry for more accurate cost estimating for early phase project planning.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

1. A method of visual cost estimating for early phase project planning comprising:
providing a graphical user interface comprising a scaled workspace corresponding to a project space;
placing a graphical representation of project items on or within the scaled workspace;
adjusting a layout of one or more project items on or within the scaled workspace according to a predetermined rule comprising ignition spacing or radiation spacing relating to one or more project items previously placed;
adjusting a quantity of one or more project items previously placed based on the layout of one or more project items on or within the scaled workspace or adding one or more project items to the scaled workspace based on the layout of one or more project items previously placed or a relationship between two or more project items previously placed; and
generating a visual cost estimate comprising a visual depiction of costs integrated with a display of the layout of project items on or within the scaled workspace.

2.-4. (canceled)

5. The method of claim 1, wherein the scaled workspace comprises a two-dimensional representation of the project space.

6. The method of claim 1, wherein the scaled workspace comprises a three-dimensional representation of the project space.

7.-12. (canceled)

13. A non-transitory computer readable medium comprising software instructions that, when executed by a processor, perform a method of visual cost estimating for early phase project planning comprising:
providing a graphical user interface comprising a scaled workspace corresponding to a project space;
placing a graphical representation of project items on or within the scaled workspace;
adjusting a layout of one or more project items on or within the scaled workspace according to a predetermined rule comprising ignition spacing or radiation spacing relating to one or more project items;
adjusting a quantity of one or more project items previously placed based on the layout of one or more project items on or within the scaled workspace or adding one or more project items to the scaled workspace based on the layout of one or more project items previously placed or a relationship between two or more project items previously placed; and
generating a visual cost estimate comprising a visual depiction of costs integrated with a display of the layout of project items on or within the scaled workspace.

14.-16. (canceled)

17. The non-transitory computer-readable medium of claim 13, wherein the scaled workspace comprises a three-dimensional representation of the project space.

18.-20. (canceled)

21. The method of claim 1, wherein the visual depiction comprises a heatmap showing a concentration of material costs corresponding to the layout of project items.

22. The method of claim 1, wherein the visual depiction comprises a heatmap showing a concentration of labor costs corresponding to the layout of project items.

23. The method of claim 1, wherein the visual depiction comprises a heatmap showing a concentration of material and labor costs corresponding to the layout of project items.

24. The method of claim 1, wherein the visual depiction comprises a distribution of material costs corresponding to the layout of project items.

25. The method of claim 1, wherein the visual depiction comprises a distribution of labor costs corresponding to the layout of project items.

26. The method of claim 1, wherein the visual depiction comprises a distribution of material and labor costs corresponding to the layout of project items.

27. The method of claim 1, wherein adjusting the layout of one or more project items on or within the scaled workspace comprises adjusting a position of one or more project items within the scaled workspace in three-dimensions.

28. The non-transitory computer-readable medium of claim 13, wherein the scaled workspace comprises a two-dimensional representation of the project space.

29. The non-transitory computer-readable medium of claim 13, wherein the visual depiction comprises a heatmap showing a concentration of material costs corresponding to the layout of project items.

30. The non-transitory computer-readable medium of claim 13, wherein the visual depiction comprises a heatmap showing a concentration of labor costs corresponding to the layout of project items.

31. The non-transitory computer-readable medium of claim 13, wherein the visual depiction comprises a heatmap showing a concentration of material and labor costs corresponding to the layout of project items.

32. The non-transitory computer-readable medium of claim 13, wherein the visual depiction comprises a distribution of material costs corresponding to the layout of project items.

33. The non-transitory computer-readable medium of claim 13, wherein the visual depiction comprises a distribution of labor costs corresponding to the layout of project items.

34. The non-transitory computer-readable medium of claim 13, wherein the visual depiction comprises a distribution of material and labor costs corresponding to the layout of project items.

35. The non-transitory computer-readable medium of claim 13, wherein adjusting the layout of one or more project items on or within the scaled workspace comprises adjusting a position of one or more project items within the scaled workspace in three-dimensions.
